(19) United States
(12) Patent Application Publication
(10) Pub. No.: US 2005/0081908 A1
(43) Pub. Date: Apr. 21, 2005

(54) Method and apparatus for generation of electrical power from solar energy

(76) Inventor: Roger G. Stewart, Morgan Hill, CA (US)

Correspondence Address: PATRICK REILLY, BOX 7218, SANTA CRVZ, CA, 95061-7218, US

(21) Appl. No.: 10/803,543

(22) Filed: Mar. 18, 2004

Related U.S. Application Data
(60) Provisional application No. 60/456,202, filed on Mar. 19, 2003.

(51) Int. Cl. H01L 31/00

(52) U.S. Cl. 136/246

(57) ABSTRACT

A method of providing an apparatus and system comprising a complete smart solar electrical power generator system integrated into the form of a thin flat glass plate. The novel elements include: a micro-scale optical array, a new type of miniaturized photovoltaic cell, an inside-the-lens concentrator design, integral heat sinking and mechanical support, a sealed solid-state design with no air gaps and a new process for building it, combined reflective/refractive light concentration around the photovoltaic cell, variable solar concentration ratios, and a new integrated structure for interconnecting the system together.

### CROSS REFERENCE TO RELATED APPLICATIONS

This application is related to and claims priority from U.S. Provisional Patent Application No. 60/456,202, entitled “Silicon Sunflower”, filed on Mar. 19, 2003, and which is incorporated by reference in its entirety herein.

### BACKGROUND OF THE PRESENT INVENTION

1. Field of Invention

The present invention relates to generating electrical power. More particularly, the present invention relates to methods and systems for generating electrical power from solar energy.

2. Background of the Invention

The current high cost of photovoltaic solar cells is a significant barrier to widespread deployment of renewable energy sources. Currently the annualized cost of current photovoltaic solar cell systems is about 25¢/KWhr vs. only 3-4¢/KWhr for modern gas or coal burning baseline power generating plants. Current solar cell generating systems are barely competitive with even the most expensive peak power generation rates of about 20¢/KWhr. Even if cost reductions for solar electrical power generation continue at their historical rate of 8%/yr, it would take more than 20 years for solar generation to become a significant source of energy for the world's electrical power grid.

These high costs are driven mainly by the requirement for huge quantities of polysilicon, amorphous silicon, or single-crystal silicon used in their construction. The requirement for such large quantities of processed silicon wafers also raises significant environmental issues. There is, therefore, a long felt need to reduce the cost of solar electrical power generation at a faster rate then the prior art allows.

### OBJECTS OF THE INVENTION

It is an object of the present invention to provide a method to generate electrical energy from solar energy.

It is a further optional object of the present invention to provide a system that generates electrical energy from solar energy.

Additional objects and advantages of the present invention will be set forth in the description that follows, and in part will be obvious from the description, or may be learned by practice of the present invention. The objects and advantages of the present invention may be realized and obtained by means of the instrumentalities and combinations particularly pointed out in the appended claims.

### SUMMARY OF THE INVENTION

The method of the present invention provides a method, system and apparatus for generating electrical energy from solar energy.

In a first preferred embodiment of the present invention, a unique planar concentration panels reduces silicon usage to approximately less than 1% of what is required today and supports a reduction in the overall cost of solar based electrical power generation to about 12¢/KWhr. Availability of these new photovoltaic electric power generators, will support an acceleration of a transition to renewable solar energy, and a general adoption of solar based electrical power generation by about 10 years.

The method of the first preferred embodiment of the present invention, or silicon sunflower, employs a novel solar concentrator that permits generation of roughly 400 times as much power from a silicon wafer as could be achieved with a direct-sunlight solar panel. Since the silicon is used more efficiently, more sophisticated silicon photovoltaic cells can be used to double the sunlight-to-electricity conversion efficiencies from roughly 12% for direct-sunlight cells to over 25%. The silicon sunflower thus captures some of the benefits of solar concentrators, yet the silicon sunflower may be scaled and implemented, in certain alternate preferred embodiments of the present invention, in a way that overcomes the thermal and mechanical drawbacks of conventional solar concentrator devices.

A silicon sunflower may comprise or be comprised within a complete smart solar electrical power generator system integrated into the form of a thin flat glass plate. The novel elements of the silicon sunflower may include one or more of the following elements: a micro-scale optical array, a new type of miniaturized photovoltaic cell, an inside-the-lens concentrator design, integral heat sinking and mechanical support, a sealed solid-state design with no air gaps and a new process for building it, combined reflective/refractive light concentration around the photovoltaic cell, variable solar concentration ratios, and a new integrated structure for interconnecting the system together.

Certain still alternate preferred embodiments of the present invention comprise a photovoltaic device for concentrating sunlight into multiple photo voltaic cells may comprise one or more of the following elements:
> a metallic bottom structure with a multiplicity of indentations, each containing a photo voltaic cell;
> a transparent top structure containing multiple optical devices, such top structure aligned to the bottom layer such that some of the optical devices are positioned over each indentation in the metallic bottom layer, with some of the optical devices concentrating the incident sunlight to the photovoltaic cell;
> indentations in the metallic bottom layer function as optical reflectors, reflecting sunlight into the photo voltaic cells allowing an additional opportunity to capture the sunlight;
> a metallic bottom layer that functions as a thermal conductor, conducting excess heat away from the photo voltaic cells;
> a metallic bottom layer that is bonded directly to the transparent top structure with an adhesive;
> a metallic bottom layer is separated from the transparent top layer containing multiple optical devices by airspace;
> multiple optical devices in the transparent top layer comprising spherical lenses;
> multiple optical devices in the transparent top layer comprising cylindrical lenses;
> multiple optical devices in the transparent top layer comprising compound lenses;
> multiple optical devices in the transparent top layer comprising Fresnel lenses;
> transparent top structure comprising a low-cost pressed glass plate;
> a metallic bottom layer having thickness or composition of altered to maximize thermal conduction;
> a plate is steered to track the sun using power and control from the control sections of the plate;
> some control regions lack a concentrator lens and are used to power the control circuits and steering motors;
> some control regions have a weak or “soft” concentrator lens and are used for acquiring the sun;
> some photovoltaic cells may be mounted in a recess on the metallic layer;
> recessed regions are formed by embossing;
> metallic bottom layer is aluminum foil;
> the plate is steered to track the sun using power and control from the control sections that are less affected by weather;
> photovoltaic cells in the control sections are larger or more numerous than they are in the concentrator sections;
> the power consuming devices are integrated circuits, and the miniature photovoltaic cells and power-consuming devices are freed from wafers using NanoBlock IC technology;
> miniature photovoltaic cells are cut from wafers using a laser;
> miniature photovoltaic cells are located in embossed recessed areas using a Fluidic Self-Assembly Process;
> an electrically conducting layer is applied with a thick film process;
> an electrically conducting layer is applied with a thin film process;
> a metallic layer serves as an electrical ground for the system;
> only one contact must be made to the top surface of each photovoltaic cell;
> electrical connection within the apparatus is a eutectic bond, conductive epoxy, silver paste or other suitable technique known in the art; and
> a weather and abrasion resistant coating is applied to the back of the metallic bottom layer.

### BRIEF DESCRIPTION OF THE DRAWINGS

The accompanying drawings, which are incorporated in and constitute a part of the specification, illustrates a preferred embodiment of the present invention and, together with a general description given above and the detailed description of the preferred embodiment given below, serve to explain the principles of the present invention.

FIG. 1 is an illustration of a first preferred embodiment of the present invention;

FIG. 2 is a cross-sectional view of the first preferred embodiment of FIG. 1;

FIG. 3 is an expanded cross-sectional view of a generation layer of the first preferred embodiment of FIG. 1;

FIG. 4 is an illustration of a fabrication process for building the generation layer of FIG. 3.

FIG. 5 is an expanded top view of the generation layer of FIG. 3.

FIG. 6 is an illustration of electrical interconnect of Si PV cells of the first preferred embodiment of FIG. 1;

FIG. 7 is an illustration of carrier recombination suppression in the photovoltaic cells of the first preferred embodiment of FIG. 1;

FIG. 8 is an illustration of aspects of the steering and control systems of the first preferred embodiment of FIG. 1; and

FIG. 9 is an illustration of an alternative embodiment having a waffle structure.

### DETAILED DESCRIPTION OF A PREFERRED EMBODIMENT

Reference will now be made in detail to the present preferred embodiments of the present invention as illustrated in the accompanying drawings.

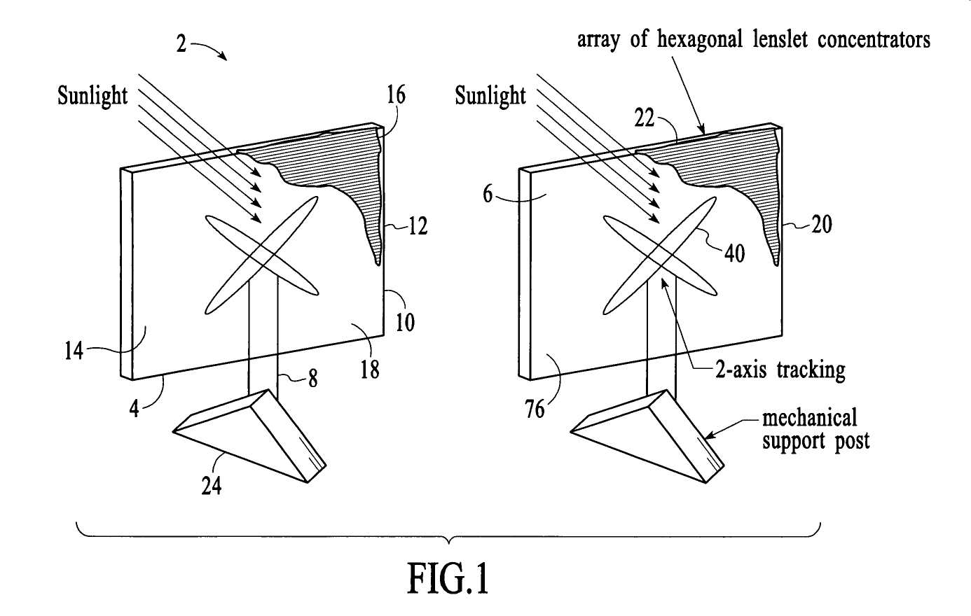

Referring now generally to the Figures and particularly to FIG. 1, FIG. 1 presents a first preferred embodiment of the present invention 2, or silicon sunflower 2, includes a miniaturized concentrator array plate 4 that may be fabricated as 0.5×0.5 meter (20 inch square) glass plates 6 on a 2-axis steering mount 8. Each plate 6 is about 8-9 mm thick with a flat surface 10 on the back 12 and a pressed-glass front surface 14 forming a multiplicity of small hexagonally shaped lenses or lenslets 16.

Both the silicon photovoltaic devices 18, or photovoltaic cells 18, and the control electronics 20 are integrated into an electrical power generation layer 22 that is laminated onto the back surface 12 of the glass plate 6. Signals and power from this generation layer 22 are also used to drive tiny motors 24 in the 2-axis mount 8 to keep the concentrator array plate 4 pointed at the sun.

Implementation of this micro-array concentrator concept may in certain yet alternate preferred embodiments of the present invention include the application of a miniaturized photovoltaic solar cell 24 that is described in more detail below.

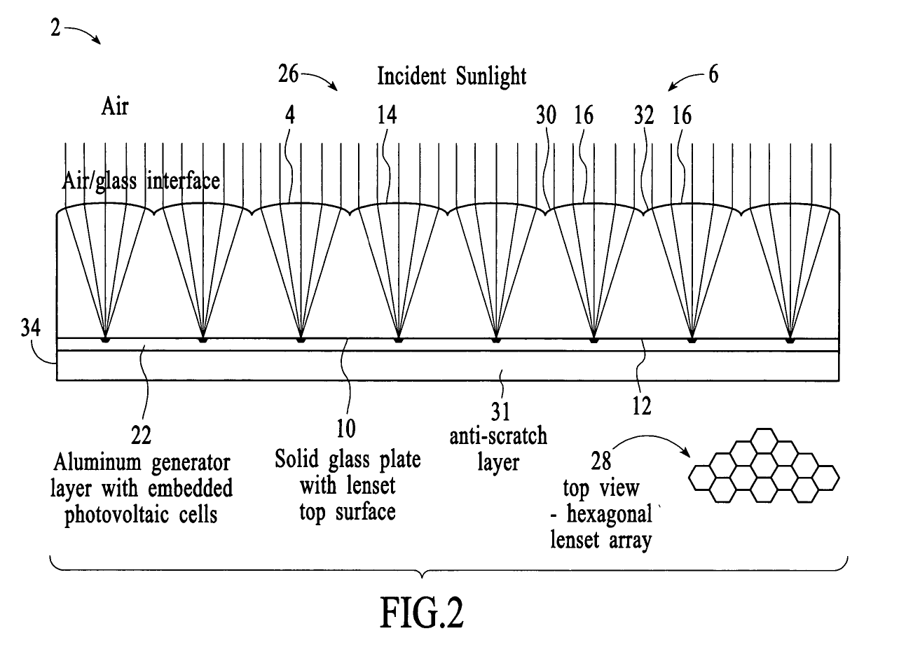

Referring now generally to the Figures and particularly to FIG. 2, FIG. 2 is a cross-section of the concentrator array plate 4. The cross-section shows a 40mm section of a glass concentrator array 26. In this case the cross-section was taken along a line connecting the flat sides of the hexagonal lenslet pattern 28 on the top surface 30 of glass plate 6. The thickness of the glass plate 6 ranges from a minimum 8 mm thickness where the lenslets 16 abut one another, to a maximum 9 mm thickness near the center of each lenslet 16.

The shape of each of these lenslets 16 is designed to function as a F/1.6 lens with a 5 mm diameter (across the flats) and an 8 mm focal length. Each plate 4 contains approximately 14,000 of these lenslets 16 and their associated miniature photovoltaic devices 31, whereby a density of 58,000 lenslets/m² is achieved.

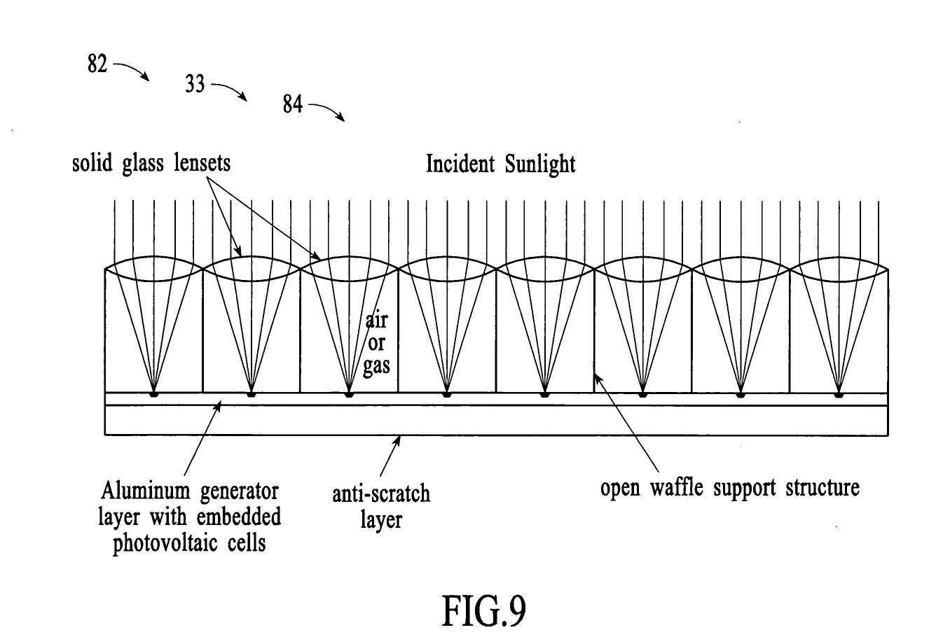

Although shown as an array of simple glass lenslets 32, it is known to those skilled in the art that other optical structures or materials could be substituted for those shown here without deviating from the present invention. For example, Fresnel or diffractive lenses could be used in place of the simple lenslets 16 shown here. The concentration could be done in only one axis instead of both axes as shown here. The glass plate 6 could be replaced with a suitable plastic or other suitable materials known in the art. The plate size, lenslet size, or focal length could be made either smaller or larger. And the solid structure of the silicon sunflower 2 as shown in FIG. 1 could be replaced with a hollow waffle structure 33 if needed to reduce weight as shown in FIG. 9.

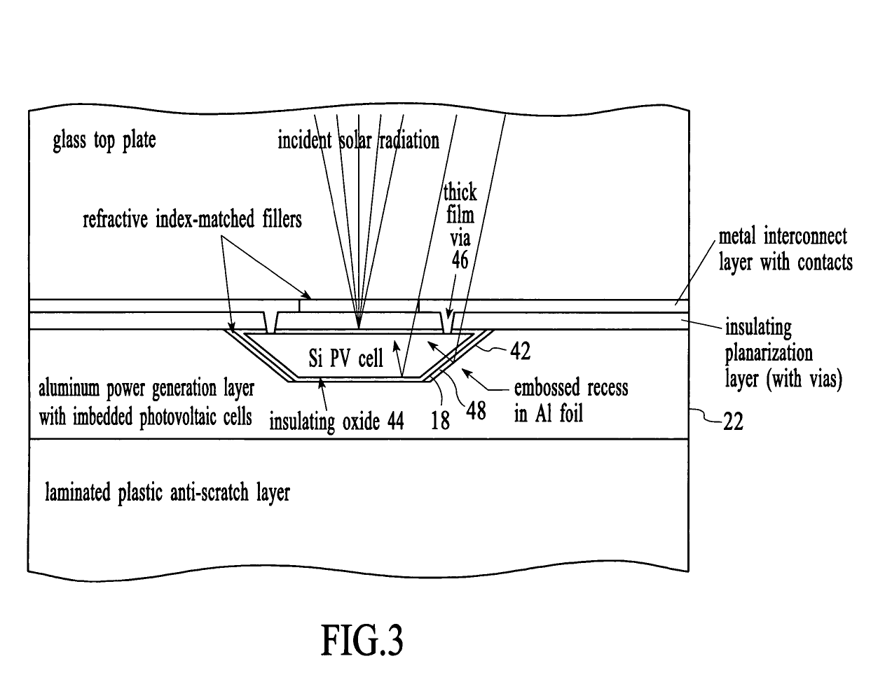

The generation layer 22 shown is preferably laminated to the flat back surface 12 of the concentrator array glass plate 6. This generation layer 22 is preferably composed mainly of aluminum foil approximately 200 μm thick. In some cases, another layer of organic or inorganic material—perhaps 500 μm thick—may also be added to protect the aluminum foil 34 from scratches or other mechanical damage, and as shown in both FIGS. 2 and 3.

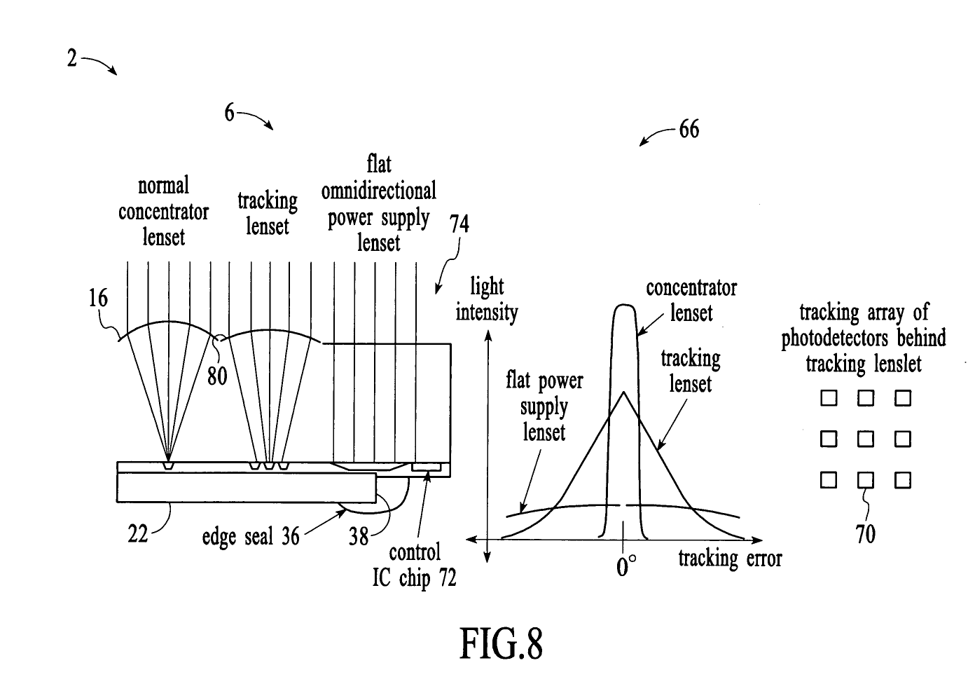

The miniaturized silicon photovoltaic devices 18 shown in FIG. 2 and FIG. 3 are sandwiched in between the glass concentrator plate 6 and the aluminum generator plate 22. When hermitic edge seals 36 are added at the perimeter of this 500 mm square plate 6 as shown in FIG. 8, both the silicon photovoltaic cells 18 and the control electronics 20 are thereby hermitically sealed between a glass plate 6 that is an excellent barrier to water and contaminates on one side and an aluminum generation layer 22 that is also impervious to water and contaminate intrusion on other side.

The edge seals 36 can be made by stopping the aluminum generator layer 22 a couple millimeters inside the edge 38 of the glass 6 as shown in FIG. 8. The place where the outside edge of the aluminum layer 22 makes contact with the 12 side of the glass plate 6 can then be sealed with a bead of epoxy, a glass frit, by depositing a layer of aluminum or other metal to cover up and seal the junction, or other techniques used for sealing AMLCDs and other flat panel structures. This sealed and self-contained structure of the silicon sunflower 2 could continue generating electricity for extended periods without maintenance.

Note that the concentrator array plate 4 is strong and stiff enough to support itself and can therefore be directly attached to a minimal support structure as shown in FIG. 1. In most cases the concentrator array plate 4 can be directly connected to the aluminum yoke and steering structure 40 with a simple adhesive.

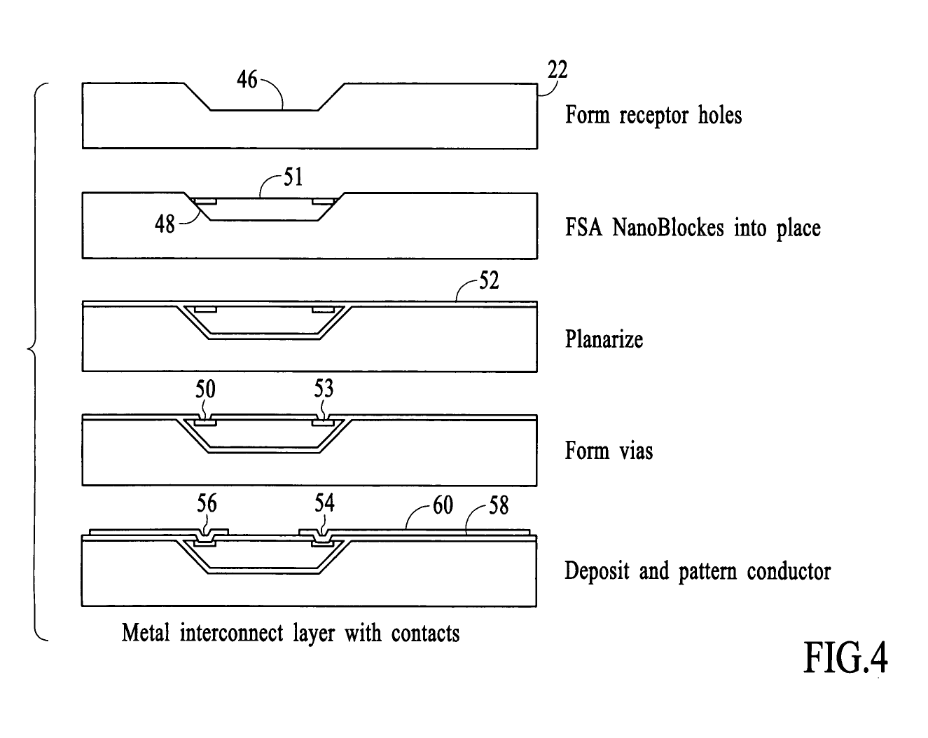

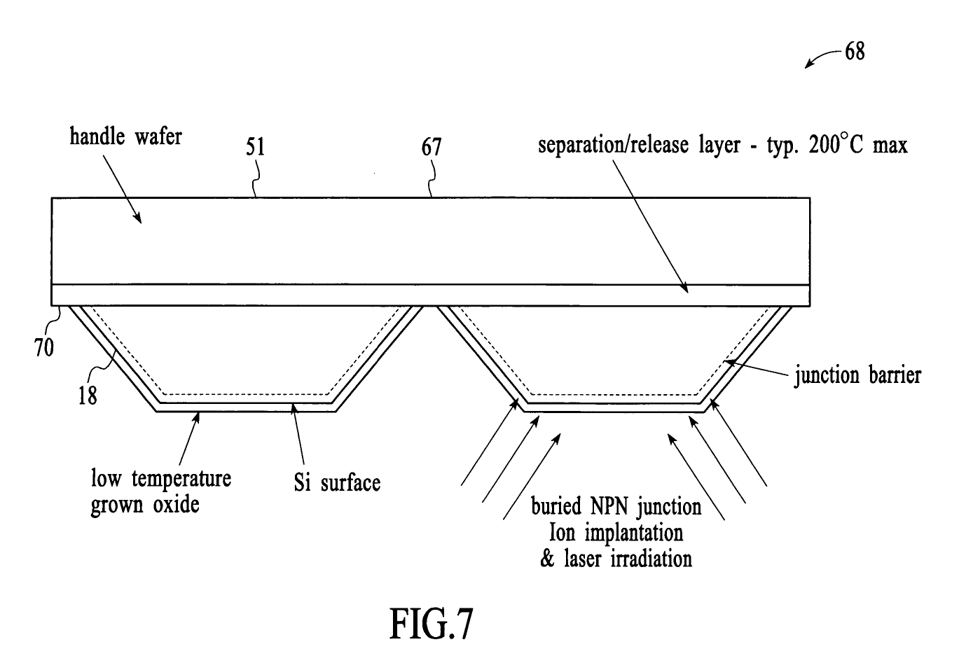

Referring now generally to the Figures and particularly to FIG. 3, FIG. 3 illustrates a silicon sunflower power generation layer 22. FIG. 3 provides a magnified cross-sectional view of one of the 8 photovoltaic cells 18 as shown in FIG. 2. The Si PV cell 18 has a trapezoidal shaped cross-section as shown in FIG. 3 and rectangular shape viewed from the top, as per FIG. 4, and measures 250 μm×350 μm by 50 μm thick. The Si PV cell 18 is fully recessed in a receptor hole 42 that is embossed into the aluminum foil layer 22. As shown in FIG. 3, all six surfaces of the Si PV cell 18 are covered with an insulating oxide 44, e.g. SiO₂ or Si₃N₄ as described in more detail in the description of FIG. 7, to prevent electrical contact between any part of the silicon PV cell 18 and the aluminum foil layer 22—except where silicon vias are formed through these insulating oxides on the top surface 46 of the PV cell 18.

Since the solar collector plate is a completely solid structure with no air gaps, even the small micro-scale gaps that could otherwise exist at the edge of the block or on top the planarization layer, are preferably filled or covered with an index-matched organic filler material. Electrical contact to the PV cells 18 is achieved with a deposited thick film metallization layer (typically a silver/organic composite material).

Several features of the structure enhance concentration of the light into the silicon photovoltaic device 18. Instead of using a separate lens 16 that forms an image some distance away in air, in accordance with the method of the present invention, the bending of light and formation of the image may be accomplished within a single solid block of glass. Since the image of the sun is formed within the lens itself instead of outside of the lens, the image size is reduced in proportion to the index refraction of the glass, which in this example is 1.5. This means that the solar image is only about 48 μm in diameter wherein in a conventional lens design it would be 70 μm. This effect also means that the silicon sunflower 2 can collect and convert into electricity light from a wider range of “acceptance angles” totaling 2.5° instead of the 1.5° acceptance angle limit with a conventional lens system with the same size photovoltaic device. The inventive, novel and unique lens structure of the silicon sunflower 2 relaxes the tracking precision needed in the mechanical support system, and permits higher efficiencies to be achieved with smaller solar cells designed and implemented in accordance with the method of the present invention.

Note also that the sides of the aluminum recess containing the photovoltaic device 18 are highly reflective and angled to maximize the concentration of sunlight within the photovoltaic device 18. As shown in FIG. 3, light that passes completely down through the photovoltaic cell 18 and might be lost in a conventional design, is instead reflected back up though the photovoltaic cell a second time and has another chance to produce electricity. Even light that misses the photovoltaic cell 18 entirely on the first pass has an opportunity to strike the reflective slanted sidewall of the embossed recess and then pass through the photovoltaic device 18.

Note also how both the scale and structure of the photovoltaic device 18 eliminates some or all of the thermal issues normally associated with a concentrator-based solar collector system. While concentrating the light on a micro-scale, the structure of the silicon sunflower 2 disperses the light on the scale where thermal issues are important. While the total collimated incident radiation from the sun is 850 watts/meter, in the design of the silicon sunflower 2 this power is split up among 56,000 separate micro-concentrators so that the total incident radiation-per-photovoltaic-device is only 15 mW each. With 25% conversion efficiency, the thermal budget is reduced to only about 11 mW/device.

In addition, the structure of a small, thin silicon photovoltaic device 18 recessed into and in intimate contact with a layer of solid aluminum 22 is ideal for transferring heat from an optical concentration site into the aluminum layer 22. While not normally considered thick enough for a good heat sink, when taken in scale with the 50 μm thick silicon photovoltaic devices 18 and the short thermal spreading distance of only 2 mm, the thermal gradient across even the 200 μm thick aluminum foil 22 is small. The net effect of the silicon sunflower 2 is a structure with a local thermal resistance of about 120°/watt/cell, but an effective average thermal resistance that is less by a factor of 56,000—or only 0.002°/watt/m². The total local temperature rise at the optical concentration site is therefore limited to less than 2° C. which is insignificant compared to the 20° C. average temperature rise in response to the total 1,000 watt/meter radiation exposure. The structure of the silicon sunflower 2 shown in FIG. 3, therefore provides the full economic benefits of a concentrator system, without the disadvantages of higher operating temperatures normally associated with concentrators.

Referring now generally to the Figures and particularly to FIG. 4, FIG. 4 illustrates the process steps used to fabricate the silicon sunflower 2. In the preferred embodiment, processing begins by embossing precise 52 μm receptor holes 46 into a sheet of aluminum foil 22 that is approximately 200 μm thick. This is preferably done with a pair of pinch rollers on an industry-standard 500 mm wide web fabrication line using methods known to those skilled in the art.

In preparation for assembly of the silicon sunflower 2, a silicon wafer 51 is processed to form high-efficiency photovoltaic solar cells 18 suitable for use in solar concentrator systems. These silicon processes are also is also well known to those skilled in the art. These silicon wafers 51 are then thinned to 50 μm (about 2 μm thinner than the recess hole is deep) and formed into a preferably tapered shape that fits the size and shape of the embossed receptor holes 46. This may be done in a number of ways including an etched “NanoBlock” formation technique published by the Alien Technology Corporation, or by laser cutting the wafer 51 directly, or other suitable means or technique known in the art.

Once a plurality of silicon photovoltaic chips 48 and the aluminum foil 22 have been pre-formed as described above, they are then brought together on a web processing line to place one silicon photovoltaic chip 48 into each receptor hole 46. This can be done with a number of processes including using industry-standard “pick-and-place” machines; using a “Vibratory Self-Assembly Technique” such as that described and published by MIT; or using a “Fluidic Self-Assembly Process” as published by the Alien Technology Corporation.

After one silicon photovoltaic chip is positioned into each receptor hole 46, or most receptor holes 46, the silicon photovoltaic chips 48 are locked into place and air gaps are filled by adding a planarization layer 52 over the top of the structure as shown in FIG. 4. This locating and securing of the silicon photovoltaic chips 48 can be done using several known techniques including roller coating, meniscus coating, or spin coating of a viscous fluid over the surface that is subsequently allow to dry or polymerize into a electrically-insulating photosensitive solid film. Planarization can also be achieved by laminating a 10-20 μm thick photosensitive layer over the top of the structure that is inexpensive, and seals the structure at the surface but is less effective at filling in the sidewall cavities.

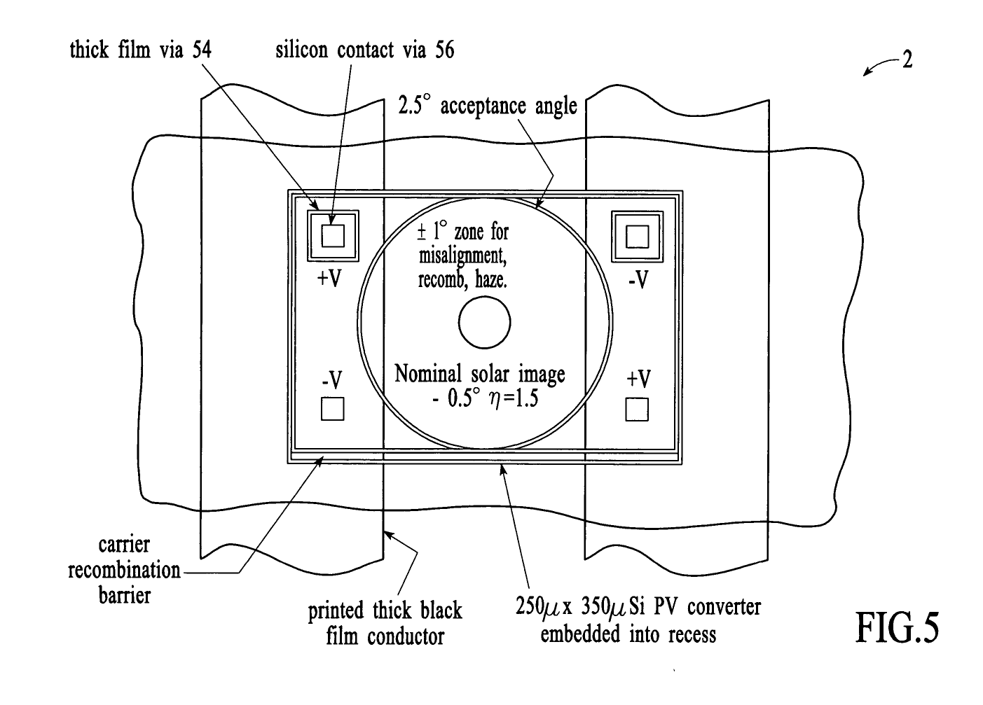

Next, a plurality of thick film vias 53 are formed through the planarization layer 52 as shown in FIGS. 4 and 5. This may be done using several techniques well known to those skilled in the art including photo-exposure through a mask to polymerize and harden the regions outside the via followed by development and removal of the planarization material 52 in the via 53; laser drilling of vias 53 through the planarization material 52; conventional masking and exposure using a separate photoresist followed by chemical or plasma etching of the vias 50; etc. As shown in FIGS. 4 and 5, whether or not electrical contact is made through the vias 50 to the underlying photovoltaic devices 18 depends on whether or not the thin film via 54 is aligned over a silicon contact via 56. Contact to a metallization film 58 is only achieved when both the silicon via 56 and a thin film via 54 are both present and aligned to each other.

Next an interconnect metallization layer 60 is deposited over the silicon wafer 51 to interconnect the silicon photovoltaic cells 18 to each other and to other elements of the silicon sunflower 2. As shown in FIGS. 4, 5, and 6, the interconnect metallization layer 60 may be applied with a thin film, thick film, or other commonly used metallization process. The metal layer 60 is typically between 0.5 and 20 microns thick, with a resistivity of less than 0.1 ohm/square.

After completing the fabrication steps shown in FIG. 4, the aluminum foil generator layer 22 is next aligned to and then laminated to the flat back surface 12 of the glass concentrator array plate 4. An index of refraction matching adhesive may be used between the glass plate 6 and the top surface of the generating layer 22 as shown in FIG. 3.

An edge seal 64 is then formed between the aluminum generator layer 22 and the glass concentrator array plate 6 as described above.

Other layers may subsequently be added to protect the backside of the aluminum foil 22 to protect it from scratches, corrosion, or other environmental factors. Still other layers may be added for aesthetics, identification, or other purposes.

Finally, the silicon wafer 51 is coupled to the 2-axis pointing mount 8 shown in FIG. 1. Preferably this is done with an epoxy adhesive.

Referring now generally to the Figures and particularly to FIG. 5, FIG. 5 is a top view of the Silicon Sunflower generation structure. The 250 μm×350 μm silicon photovoltaic chip 18 is shown tightly recessed in its receptor hole. For this lenslet concentrator array 32 with a focal length of 8 mm, the nominal solar image is calculated as:
tangent (angle subtended by the sun)×(lenslet focal length)/(index of refraction of glass)=tangent 0.5°×8 mm/1.5=48 μm

Note that despite the small size of the photovoltaic cell 18, there is still a generous margin for runout, edge re-combination, and other sources of misalignment between the nominal and actual location of the solar image relative to the edge of the silicon photovoltaic device 18. Note also that mechanical misalignment between the concentrator array 32 and the generator layer 22 plus some tracking errors in the 2-axis mechanical mount may be compensated for by the integrated tracking subsystem 66 described below. The tracking subsystem 66 will compensate for misalignment errors of up to ±1 mm and/or tracking and set up errors of up to about ±5°. The tracking subsystem 66 is less tolerant to runout errors between the glass plate 6 and the aluminum generator film 22—in this case they must not exceed the ±100 μm tolerances that are readily attainable with modern thin film and thick film high-volume roll-to-roll web processing machines.

Finally, note the presence of a carrier recombination barrier 68 at both the edges and the backside of the silicon sunflower 2 to prevent electrons and holes from diffusing to the edges of the silicon sunflower 2 and/or to minimize the carrier recombination rate at those edges.

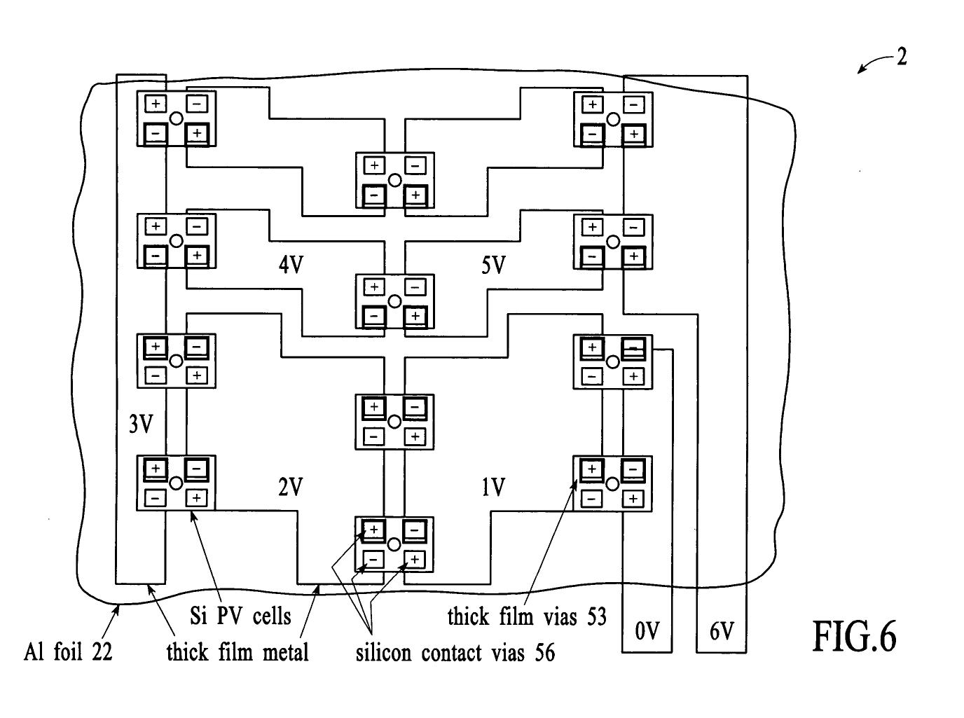

Referring now generally to the Figures and particularly to FIG. 6, FIG. 6 provides an example of how the individual photovoltaic cells 18 may be connected to each other in both serial and parallel combinations. In FIG. 2 twelve photovoltaic cells 6 are connected with six in series times, two in parallel to provide an output voltage of about 6V assuming that each cell produces about 1V of EMF. The key feature of the design of FIG. 6 is in using both the patterning of the metallization in combination with the presence-or-absence of a thin film via to chose which of the silicon vias 53 will be used and to where it will be connected. It is clear to those skilled in the art that many other combinations are possible including additional internal connections to control IC chips and batteries, external connections to drive steering motors, and external connections used to export power.

Referring now generally to the Figures and particularly to FIG. 7, FIG. 7 is an illustration of the miniaturized silicon photovoltaic cells 18 of the Silicon Sunflower 2. Certain preferred embodiments of the present invention work best with highly miniaturized micro-concentrators—typically 56,000 per square meter. This in turn requires using photovoltaic cells 18 that are roughly 100 times smaller in area than prior art solar concentrator cells. One barrier to making such cells work efficiently, is the fact that hole-electron pairs are being generated closer to either the edge or the bottom of the chip and may therefore more readily diffuse to the surface where there are numerous traps that would accelerate thermal recombination of the holes and electrons. This trap-induced re-combination subtracts from the current supplied by the cell 18 and thereby reduces the efficiency of the photoelectric conversion process.

FIGS. 5 and 7 show three techniques to minimize efficiency losses in the method of the present invention and as embodied in the silicon sunflower 2. First, an internal optical lens helps by concentrating the solar image into a smaller portion of the silicon chip 51, thereby maintaining a larger nominal distance to the perimeter edge of 100 microns.

Second, a two-layer NPN structure 67 may be formed on both the edges and back surface of the semiconductor chip 51 to create a junction barrier to the diffusion of holes and electrons out to the edge itself. This could be done by first using a N-doped substrate doped to about 1 ohm-cm. Then during processing of the wafer 51 into NanoBlocks using Alien's published process, there is a point shown in FIG. 7, where all of the silicon photovoltaic cells 18 are still attached to the handle wafer 68 via the separation or release layer 70. At this point, the wafers 51 are inserted into an industry-standard high-current ion implantation machine that implants boron with energy of about 200 KV. This implant is then followed with a lower energy phosphorous implant at about 20 KV. The implanted layers are then activated with a short-pulse laser of approximately 20 ns duration sufficient to raise the temperature of the outer 0.5 μm region of the silicon wafer 51 to about 900° C. without raising the temperature of the top surface of the wafer 51 to above 200° C. This is sufficient to activate the implanted layers and create a continuous region of back-to-back diode structure about 0.5 μm inside from both the back and side edges of the wafer 51. This configuration of the wafer 51 may block the diffusion of either electrons or holes from diffusing to and recombining at the back and side edges of the chip.

Third, the recombination velocity of holes and electrons at the edge and back surfaces of the silicon PV chip 18 may be reduced by reducing trap densities to levels comparable to the low 10¹²/cm² levels typically found on the top surface of the chip. Like the ion implantation described above, this surface treatment is best done immediately before removal of the handle wafer 68 as shown in FIG. 7. In this case, the surface of the handle wafer 68 is first wet etched to establish a smooth surface with minimal stress fractures. Then an ultra-low-temperature thermal oxide like SiO₂ or Si₃N₄ may be grown on both the side edges and backside of the chip 18 using plasma enhanced thermal oxidation or other similar techniques currently used to grow or form high-quality gate dielectrics on polysilicon transistors at temperatures below 200° C.

Referring now generally to the Figures and particularly to FIG. 8, FIG. 8 illustrates integrated steering control of the silicon sunflower 2. While most of the surface of the concentrator array plate are filled with simple micro-solar collectors, FIG. 8 shows the sensors 70 and control electronics 72 that are present in the extreme corners 74 of the plate 6. In these corners 74, both the lenslet arrays and the underlying electronics are modified to provide integrated steering and control of the array. Sensor readings taken in all four corners are averaged together to determine the optimum pointing direction for the plate. Alternatively, a single sensor could be used if it were located near the center of the plate.

In one portion of the corner 74, as shown in FIG. 8, the concentrator lenslet 16 on the top surface of the concentrator array plate is replaced with a simple flat surface and the concentrator PV cells below it are replaced with conventional 1× solar cells 76 that are 100× larger than the concentrator cells located elsewhere. These 1× solar cells 76 (4 out of the 14,000 per plate) are designed to provide for the minimal power required for control and steering, independent of the direction of the sun or whether or not clouds might obscure the sun. Additional control IC chips 72 may be located in or near the corner as shown in FIG. 8.

In another four out of 14,000 sections, the concentrator lenslet 16 is replaced with a tracking lenslet 80 suitable for tracking the sun using a small array of tracking photo detectors 82 as shown in FIG. 8. Unlike the concentrator lenslet 16 that is sharply focused on the sun and provides negligible illumination outside of its narrow acceptance angle, the tracking lenslet 80 drops off gradually with increasing misalignment error and therefore provides a useful tracking differential that the electronics monitoring the tracking matrix can use to aim the plate. Also, in contrast to the flat plate shown in FIG. 8, the tracking lenslet 80 shows a much stronger variation with angular misalignment error than does the omni-directional flat plate section.

These power supply segments, sun sensor arrays, and control logic provide the tracking signals needed to always keep the silicon sunflower 2 pointed at the sun. A small thin film rechargeable battery may also be included to allow the silicon sunflower 2 to re-aim after the sunset, to point back east to catch the morning sun without delay, or to handle other situations where even the omni-directional power generators can't produce enough power to control and steer the concentrator array plate 4. Integrating all of these differently shaped lenslets 16, 80, sensors, batteries, control logic, etc. into a single solid sealed plate structure of the silicon sunflower 2 as describe herein, has many advantages including robustness, hermiticity, and reduced cost. Also when built this way, the sensor feedback mechanism may also cancel out fabrication alignment errors between the concentrator array plate 4 and the generator layer 22, as well as set up alignment errors.

Referring now generally to the Figures and particularly to FIG. 9, FIG. 9 is a second embodiment of the present invention 82 having a waffle lens structure 84. Although providing two detailed preferred embodiments, it is clear to those skilled in the art that many variations can be made on this design without deviating from the inventive concepts described herein. One such variation is shown in FIG. 9 wherein the solid concentrator array plate 4 shown in FIG. 2 is replaced with the waffle structure 84. This modified structure could prove useful in applications where the weight must be reduced, or where use of larger silicon photovoltaic cells forces the size of the silicon sunflower's 2 local concentrators to be increased.

Certain additional alternate preferred embodiments may comprise one or more of the following aspects and elements:
> a photovoltaic device for concentrating sunlight to multiple photo voltaic cells having a metallic bottom structure with a multiplicity of indentations, each indentation containing a photo voltaic cell;
> a transparent top structure containing multiple optical devices, the top structure aligned to the bottom layer such that some of the optical devices are positioned over each indentation in the metallic bottom layer, with some of the optical devices concentrating the incident sunlight to the photovoltaic cell;
> photovoltaic device for concentrating sunlight to multiple photovoltaic cells having (1.) a bottom structure with a multiplicity of photovoltaic devices, (2.) a transparent top structure containing multiple optical devices, such top structure aligned to the bottom structure such that some of the optical devices are positioned over photovoltaic devices in the bottom structure, with each optical device concentrating the sunlight onto the photovoltaic device, and wherein such multiple optical devices are either square, rectangular, or hexagonal and form an array that covers virtually the entire surface of the top structure;
> a photovoltaic device for concentrating sunlight to multiple miniature photovoltaic cells having a bottom structure with a multiplicity of photovoltaic cells, a transparent top structure containing multiple optical devices, the top structure aligned to the bottom structure such that some of the optical devices are positioned over each photo voltaic cell, with each optical device concentrating the incident sunlight unto the photo voltaic cell, wherein the micro-photocells are each less than 1 mm in size and are interconnected together with a thick film or thin film process;
> a method for producing electricity wherein sunlight is locally concentrated onto a multiplicity of miniaturized structures for conversion into electricity, while avoiding the concentration of heat by limiting the power level at each concentration site to less than 1 watt:
> a photovoltaic device for concentrating sunlight onto multiple miniaturized photovoltaic cells having (1.) a bottom structure with a multiplicity of photovoltaic cells, (2.) a transparent top structure containing multiple optical devices, the top structure aligned to the bottom structure such that some of the optical devices are positioned over each photovoltaic cell, with each optical device concentrating the incident sunlight unto the photo voltaic cell, and the bottom structure including means for spreading heat away from the light concentration region such that the temperature differences between the concentration site and the rest of the bottom structure are minimized, wherein the temperature of the bottom structure is uniform to within 20 degrees Celsius;
> a photovoltaic device for concentrating sunlight onto multiple miniaturized photovoltaic cells having (1.) a bottom structure with a multiplicity of photo voltaic cells, and (2.) a transparent top structure containing multiple optical devices, the top structure aligned to the bottom structure such that some of the optical devices are positioned over each photovoltaic cell, with each optical device concentrating the incident sunlight unto the photovoltaic cell, wherein the photovoltaic device is a sealed solid structure without any gaps or voids;
> a self-supporting photovoltaic device for concentrating sunlight to multiple miniaturized photovoltaic cells having (1.) a bottom structure with a multiplicity of photovoltaic cells, (2.) a transparent top structure containing multiple optical devices, the top structure aligned to the bottom structure such that some of the optical devices are positioned over each photovoltaic cell, with each of the optical devices concentrating the incident sunlight unto the photovoltaic cell, wherein the transparent top structure provides enough mechanical strength, rigidity, and stability to permit the photovoltaic device to be self-supporting;
> a method for concentrating light in a photovoltaic device wherein light is made to execute multiple passes through the photovoltaic device using a combination of reflective and refractive containment;
> a photovoltaic device for concentrating sunlight onto a multiplicity of miniaturized photovoltaic cells that is configured as a thin, flat plate;
> an optical device that absorbs incident light over one narrow range of angles, and reflects light at all other angles;
> a system for producing electricity from sunlight wherein sunlight is concentrated onto some photovoltaic cells, sunlight is less concentrated onto other photovoltaic cells, and wherein sunlight is not concentrated significantly onto a third set of photovoltaic cells;
> a method for producing electricity from sunlight wherein some sections of the system utilize concentrated sunlight to minimize cost, and wherein other sections of the system utilize less concentrated sunlight to maximize system reliability;
> a system for locally concentrating sunlight onto a layer of multiple miniaturized photovoltaic cells that can operate independently on a stand-along basis, having (1.) a metallic bottom layer containing multiple sections, (2.) a majority of the sections are concentrator sections that contain a photovoltaic cell, and (3.) a minority of the sections are control sections;
> a transparent top layer containing multiple sections, each section corresponding to a section in the metallic bottom layer wherein each section of the top layer corresponding to a majority section of the metallic bottom layer contains one optical device positioned over the concentrator region in the metallic second layer, with each optical device concentrating the incident sunlight onto the photovoltaic device;
> a device for concentrating sunlight to multiple photovoltaic cells capable of solar tracking under concentration-adverse orientations, lighting, and weather conditions, containing (1.) a metallic bottom layer containing multiple sections, wherein (a.) a majority are concentrator sections containing a photovoltaic cell, and (b.) a minority are control sections, (2.) a transparent top layer containing multiple sections, each section corresponding to a section in the metallic bottom layer, wherein (a.) each section corresponding to a majority region of the metallic bottom layer contains one optical device positioned over the concentrator region in the metallic second layer, with each optical device concentrating the incident sunlight onto the photovoltaic device, (b.) the minority sections of the metallic bottom layer contain photovoltaic cells operating with less-concentrated sunlight so that their performance is less affected by array miss-orientation, fog, clouds, or other adverse weather conditions that would greatly decrease the effectiveness of photovoltaic devices located in the concentrator sections;
> a photovoltaic device for concentrating sunlight to multiple photo voltaic cells having (1.) a metallic bottom structure with a multiplicity of indentations, each containing a photo voltaic cell, (2.) a transparent top structure containing multiple optical devices, the top structure aligned to the bottom layer such that some of the optical devices are positioned over each indentation in the metallic bottom layer, with some of the optical devices concentrating the incident sunlight to the photovoltaic cell, (3.) an insulating layer planarizing and sealing the interstices between the photovoltaic cells or power consuming devices and the metallic substrate, and (4.) forming apertures or vias in insulating layer to permit electrical connection to the conductive regions of the photovoltaic cells and control logic,
applying an electrically conductive layer to interconnect the miniature photovoltaic cells to each other and to other electronic and electrical elements of the system
> a photovoltaic device for concentrating sunlight to multiple photovoltaic cells having a metallic bottom structure with a multiplicity of miniaturized photovoltaic cells, and a transparent top structure containing multiple optical devices, such top structure aligned to the bottom layer such that some of the optical devices are positioned over each photoelectric cells, with some of the optical devices concentrating the incident sunlight to the photovoltaic cells, wherein an electrical connection is provided between an electrically conductive region of each photovoltaic cell and the electrically conductive metallic layer;
> a method for building an integrated photovoltaic system having the steps of (a.) depositing a multiplicity of photovoltaic cells onto a planar surface, each one of which contains at least one open contact via with an exposed conductor, (b.) forming a planarizing film over the photovoltaic cells, (b.) forming planarizing vias in the planarizing film, and (c.) depositing a conductive film over the surface of the planarizing such that electrical contact is made through both the planarizing vias and the contact vias to the photovoltaic cells and such that two or more photovoltaic cells are electrically connected together via such conductive film.
> a structure for interconnecting a multiplicity of solar cells together using a single level of metallization having (1.) a photovoltaic cell with a first insulating layer on top through which two or more contact vias are formed, (2.) a second insulating layer having film vias, and (3.) a metallization layer overlaying the photovoltaic cells and making contact through both film vias and the contact vias to some but not all of the contact vias;
> a miniaturized photovoltaic cell having means for confinement of the hole-electron pairs to prevent diffusion to the edges of the chip; and
> a miniaturized photovoltaic cell having means for growing an oxide on both the edges or backside of an IC chip.

1. A photovoltaic device for concentrating sunlight to multiple photo voltaic cells comprising:
a metallic bottom layer with a multiplicity of indentations, at least a plurality of indentations containing a photo voltaic cell; and
a transparent top layer containing multiple optical devices, the top structure aligned to the bottom structure such that the optical devices are positioned over at least one indentation in the metallic bottom layer, wherein the optical devices concentrate incident sunlight towards each of the photovoltaic cell.

2. A system for locally concentrating sunlight onto a layer of multiple miniaturized photovoltaic cells that can operate independently on a stand-along basis, comprising:
a metallic bottom layer containing multiple bottom sections, wherein a majority of the multiple bottom sections are concentrator sections that contain a photovoltaic cell, and a minority of the multiple bottom sections are control sections;
a transparent top layer containing multiple top sections, each top section corresponds to a bottom section in the metallic bottom layer, wherein each section of the top layer corresponding to one of the majority bottom sections of the metallic bottom layer contains an optical device positioned over the metallic bottom layer, with each of the optical devices concentrating the incident sunlight onto one of the photovoltaic devices.

3. A miniaturized photovoltaic cell comprising means for confinement of hole-electron pairs to prevent diffusion to an edge of a semiconductor material.
